(19) United States
(12) Patent Application Publication
(10) Pub. No.: US 2013/0139594 A1
(43) Pub. Date: Jun. 6, 2013

(54) LEXVU OPTO MICROELECTRONICS TECHNOLOGY SHANGHAI (LTD)

(71) Applicants: Jianhong Mao, Shanghai (CN); Fengqin Han, Shanghai (CN); Deming Tang, Shanghai (CN)

(72) Inventors: Jianhong Mao, Shanghai (CN); Fengqin Han, Shanghai (CN); Deming Tang, Shanghai (CN)

(73) Assignee: LEXVU OPTO MICROELECTRONICS TECHNOLOGY (SHANGHAI) LTD, Shanghai (CN)

(21) Appl. No.: 13/703,568

(22) PCT Filed: Jan. 26, 2011
(86) PCT No.: PCT/CN11/70630

§ 371 Date: Jan. 31, 2013

(30) Foreign Application Priority Data
Jun. 11, 2010 (CN) 201010200713.4

(51) Int. Cl. G01P 15/08; H01L 29/84

(52) U.S. Cl. CPC G01P 15/08; H01L 29/84
USPC 73/514.01; 438/50

(57) ABSTRACT

An inertia MEMS sensor and a manufacturing method are provided. The inertia MEMS sensor includes a main body and a weight block relatively removable. The main body includes a first main body with a first surface and a second main body vertically connecting with the first surface. A first electrode parallel to the first surface is in the first main body. A second electrode perpendicular to the first surface is in the second main body. The weight block is suspended in a space defined by the first and second main bodies. The weight block includes a third electrode parallel to the first surface, a forth electrode is perpendicular to the first surface, and a weight layer. The third electrode connects with the forth electrode to form a U-shaped groove for accommodating the weight layer, thereby increasing the weight block weight, improving precision and reducing the cost.

### CROSS-REFERENCE TO RELATED APPLICATIONS

The present application claims the priority of Chinese Patent Application No 201010200713.4, entitled “Inertial micro electromechanical sensor and manufacturing method thereof”, and filed on Jun. 11, 2010, the entire disclosure of which is incorporated herein by reference.

### FIELD OF THE DISCLOSURE

The present invention relates to the field for manufacturing semiconductor apparatus, particularly to an inertia MEMS sensor and a manufacturing method thereof.

### BACKGROUND OF THE DISCLOSURE

MEMS (Micro electro mechanical system, MEMS) technology is used for a designing, processing, manufacturing, measuring and controlling micro/nanomaterial. The MEMS integrates mechanical element, optical system, driver component and electrical control system to form an entire micro system. The MEMS is commonly applied in a position sensor, rotary apparatus or inertia sensor, such as an acceleration sensor, a gyroscope and a sound sensor.

A conventional inertia MEMS sensor comprises a main body and one or more inertia weight blocks. The inertia weight block is suspended as a discrete structure with respect to the main body. The inertia weight block may be suspended and supported by a cantilever. The weight block, the main body, and a gaseous layer between the weight block and the main body constitute a capacitor. The inertia weight block and the main body may move relative to each other. When the inertia weight block and the main body move, for example laterally or vertically, relative to each other, a value of the capacitor will be changed. Speed and acceleration for relative lateral or vertical movement of the inertia weight block and the main body may be obtained by continuously measuring the value of the capacitor. The inertia MEMS sensor, which measures relative movement between the inertia weight block and the main body through measuring the value of the capacitor, is also known as a capacitor inertia MEMS sensor.

The capacitor inertia MEMS sensor is fabricated by semiconductor manufacturing process conventionally. For example, a semiconductor substrate is used as a main body of the capacitor inertia MEMS sensor and a weight block is formed to be suspended above the semiconductor substrate. Since the capacitor inertia MEMS sensor is fabricated by semiconductor manufacturing process, the capacitor inertia MEMS sensor and COMS Read-out integrated circuit (ROIC) are fabricated by the same manufacturing process in conventional technology. The capacitor inertia MEMS sensor and the COMS ROIC are fabricated on the same semiconductor substrate, that is, the capacitor inertia MEMS sensor is embedded in the COMS ROIC. An inertia sensor is disclosed in US Patent publication number 20100116057A1.

However, as dimension is reduced, films are becoming thinner, thus it is more difficult to manufacture a capacitor inertia MEMS sensor on a semiconductor substrate with CMOS apparatus therein. A weight block is usually formed by an integral conductive material. The conductive material is required to have high conductive property, stable quality and high density, such as GeSi, whereas such conductive material is expensive. Heavier the weight block is, larger inertia and higher precision the capacitor inertia MEMS sensor has. In order to improve inertia of the weight block, more conductive material will be required, thereby increasing cost of the capacitor inertia MEMS sensor.

### BRIEF SUMMARY OF THE DISCLOSURE

An object of the present invention is to provide an inertia MEMS sensor and a method for manufacturing the inertia MEMS sensor, which increases weight of a weight block thereof and which improves precision of the inertia MEMS sensor and reduces manufacturing cost.

To achieve the object, the inertia MEMS sensor includes a main body and a weight block. The main body includes a first main body with a first surface and a second main body vertically connecting with and being perpendicular to the first surface. A first electrode is provided in the first main body and is parallel to the first surface. A second electrode is provided in the second main body and is perpendicular to the first surface. The weight block is suspended in a space defined by the first main body and the second for being movable relative to the main body. The weight block includes a third electrode, a forth electrode and a weight layer. The third electrode is parallel to the first surface. The forth electrode is perpendicular to the first surface. The third electrode connects with the forth electrode to form a U-shaped groove for accommodating the weight layer therein.

Optionally, the first main body further comprises a semiconductor material layer under the first electrode, a MOS device being provided in the semiconductor material layer.

Optionally, the first electrode is made of Al, Ti, Cu, Co, Ni, Ta, Pt, Ag, Au or any combinations thereof.

Optionally, the second main body is made of silicon oxide, silicon nitride, silicon carbide, silicon oxynitride, silicon dioxide containing nitrogen and carbon, or any combinations thereof.

Optionally, the second electrode is made of Al, Ti, Cu, W, Ta or any combinations thereof.

Optionally, the third electrode and the forth electrode are respectively made of Al, Ti, Cu, Co, Ni, Ta, Pt, Ag, Au or any combinations thereof.

Optionally, the weight layer is made of W, SiGe, Ge, Al, silicon oxide, silicon nitride or any combinations thereof.

The present invention provides a method for manufacturing an inertia MEMS sensor. The method comprises following steps. A main body is provided. The main body comprises a first main body and a second main body which connect with and are perpendicular to each other. The first main body has a first surface. A first electrode is provided in the first main body and being parallel to the first surface. A second electrode being provided in the second main body and being perpendicular to the first surface. A sacrifice layer is formed on the first main body. An insulating layer is formed on the sacrifice layer. The insulating layer and the sacrifice layer form a U-shaped groove. A conductive layer is deposited on the insulating layer and the sacrifice layer. A weight layer is formed on the conductive layer, and a top of the weight layer is aligned with a top of the conductive layer on the insulating layer. The conductive layer above the insulating layer, and a part of the weight layer, are removed, until the top of the weight layer and the top of the conductive layer are respectively aligned with a top of the insulating layer. The insulating layer is removed. The sacrifice layer is removed.

Optionally, the sacrifice layer is made of carbon with purity of at least 50%.

Optionally, the sacrifice layer is formed by PECVD at temperature ranging from 350 centigrade to 450 centigrade.

Optionally, removing the sacrifice layer comprises ashing with oxygen plasma or nitrogen plasma.

Optionally, depositing a conductive layer for covering the insulating layer and the sacrifice layer is performed by CVD and/or PVD.

Compared with the prior art, the present invention has the following advantages.

The vertical capacitor and the horizontal capacitor are arranged in the inertia MEMS sensor of present invention, whereby the inertia MEMS sensor may measure movement or rotation in horizontal and vertical direction. The weight block comprises the third electrode and the forth electrode which are connected together to form a U-shaped groove with a weight layer therein. Thus the weight layer may be made of a material in low price and easy manufactured, thereby increasing weight of the weight block and reducing cost of the inertia MEMS sensor.

### BRIEF DESCRIPTION OF THE DRAWINGS

The above-mentioned object, characteristics and advantages will be clearer through the detailed description of the preferred embodiments in accordance with the present invention taken in conjunction with the accompanying drawings. The same components in the drawings are denoted with the same reference signs. The drawings, not precisely plotted according to the scale, are used to show the major ideas of the present invention. In the accompanying drawings, the thicknesses of layers and regions are scaled up for the sake of clarity.

FIG. 1 schematically illustrates an inertia MEMS sensor according to an embodiment of the present invention;

FIG. 2 schematically illustrates a flow chart of a method for manufacturing the inertia MEMS sensor of the present invention;

FIGS. 3-10 are schematic cross-sectional views for illustrating the method for manufacturing the inertia MEMS sensor of the present invention step by step.

### DETAILED DESCRIPTION OF THE DISCLOSURE

In order to decrease difficulty of fabrication in conventional technology, a weight block is usually formed by an integral conductive material. The conductive material is required to have high conductive property, stable quality and high density, such as GeSi, whereas such conductive material is expensive. For improving inertia of the weight block, more conductive material will be required, which increases cost of the capacitor inertia MEMS sensor.

An inertia MEMS sensor is provided based on inventor's numerous studies. The vertical capacitor and the horizontal capacitor are arranged in the inertia MEMS sensor in an embodiment of present invention, whereby the inertia MEMS sensor may measure movement or rotation in horizontal and vertical direction. The weight block comprises the third electrode and the forth electrode which are perpendicularly connected together to form the U-shaped groove with the weight layer therein, and thus the weight layer may be made of a material in low price and easy manufactured, thereby increasing weight of the weight block and reducing cost of the inertia MEMS sensor.

The above-mentioned object, characteristics and advantages will be clearer through the detailed description of the preferred embodiments in accordance with the present invention taken in conjunction with the accompanying drawings. When embodiments of present invention are described in conjunction with the accompanying drawings, section views will not be zoomed in according to ordinary scale, and the present invention is not limited by the specific implementations disclosed hereinafter. Three-dimensional size comprising length, width and depth should be applied in practical application.

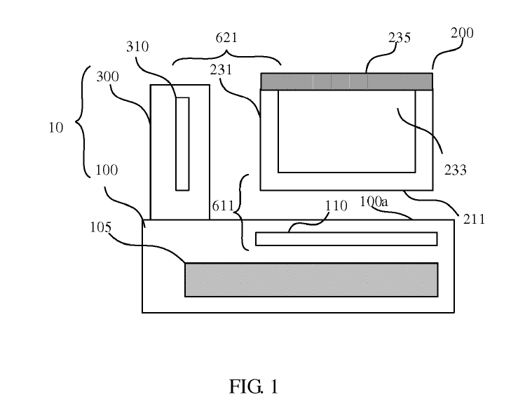

FIG. 1 schematically illustrates an inertia MEMS sensor according to an embodiment of the present invention. Referring to FIG. 1, the inertia MEMS sensor comprises a main body 10 and a weight block 200. The main body 10 and the weight block 200 are movably connected together, and thus they are movable relative to each other. When the main body 10 moves or rotates, the weight block 200 may keep quiescence and vice versa. The main body 10 and the weight block 200 may be connected referring to a connection mode of a main body and a weight block in a capacitor inertia acceleration sensor or a gyroscope, such as the weight block 200 being connected to a support ring above a semiconductor substrate through a cantilever. The weight block 200 is suspended above the main body 10 through the cantilever and the support ring. The support ring is arranged on exterior of an axis installed on the semiconductor substrate. The support ring, cantilever and the weight block may rotate around the axis, whereby the main body 10 and the weight block 200 move or rotate relative to each other.

In addition, a cantilever has a first part supporting by the main body 10 and a second part connecting periphery of the weight block 200 for suspending the weight block 200 above or beside the main body 10, thereby the weight block 200 being capable of moving relative to the main body 10.

The main body 10 comprises a first main body 100 and a second main body 300 connecting with and being perpendicularly to each other. In an embodiment, the first main body 100 is a horizontal body, and the second main body 300 is a vertical body. The first main body 100 has a first surface 100a. The first main body 100 comprises a first electrode 110 parallel to the first surface 100a therein. The second main body 300 comprises a second electrode 310 perpendicular to the first surface 100a therein.

The first main body 100 and the second main body 300 are connected together to form a L-shaped structure (one second main body 300) or a U-shaped structure (two second main bodies 300). The weight block 200 comprises a third electrode 211 parallel to the first surface 100a and a forth electrode 231 perpendicular to the first surface 100a. The third electrode 211 and the forth electrode 231 are connected together to form a U-shaped groove. The weight layer 233 is filled in the U-shaped groove. Since only periphery of the weight block 200 is made of conductive material, the structure stated above is adapted to increase weight of the weight block 200 and reduce conductive material used in fabrication.

The third electrode 211 is arranged corresponding to the first electrode 110. The third electrode 211, the first electrode 110, and a gaseous layer between the first electrode 110 and the third electrode 211 constitute a horizontal capacitor 611. The forth electrode 231 is arranged corresponding to the second electrode 310. The forth electrode 231, the second electrode 310, and a gaseous layer between the forth electrode 231 and the second electrode 310 constitute a vertical capacitor 621.

In an embodiment, one or more second main bodies 300 may be provided. The second main body 300 is made of silicon oxide, silicon nitride, silicon carbide, silicon oxynitride, silicon dioxide containing nitrogen and carbon, or any combinations thereof.

In an embodiment, the first main body 100 is a substrate. The second main body 300 is arranged on the substrate. The first main body 100 and the second main body 300 are connected together to form a L-shaped structure (one second main body 300) or a U-shaped structure (two second main bodies 300), which are completed by steps of depositing insulating material on the substrate, etching and remaining a part of the insulating material on the substrate.

In this embodiment, the first electrode 110 is made of Al, Ti, Cu, Co, Ni, Ta, Pt, Ag, Au or any combinations thereof.

In an embodiment, the second electrode 310 is made of Al, Ti, Cu, W, Ta or any combinations thereof.

In an embodiment, the third electrode 211 and forth electrode 231 are made of Al, Ti, Cu, Co, Ni, Ta, Pt, Ag, Au or any combinations thereof.

In an embodiment, the weight layer 233 is made of W, SiGe, Ge, Al, silicon oxide, silicon nitride or any combinations thereof.

The first main body 100 may further comprise a semiconductor material layer 105 under the first electrode 110. For example, the semiconductor material layer 105 is made of monocrystalline, polycrystalline, non-crystalline silicon or SiGe. It can also be made of Silicon on Insulator (SOI) or other material, such as InSb, PbTe, InAs, InP, GaAs or GaSb. A MOS device is provided in the semiconductor material layer 105.

Concretely, the weight block 200 may comprise a metal layer 235, such as an Al layer. The metal layer 235 covers the weight layer 233 and the forth electrode 231.

In the present invention, since the forth electrode 231 is arranged on sidewall of the weight block 200, and the second electrode 310 is arranged in the second main body 300, when the main body 10 moves, the weight block 200 acted upon by inertia remains at rest. If the weight block 200 moves in a direction parallel to the first surface 100a of the first main body 100, a distance between the forth electrode 231 and the second electrode 310 will be changed, thereby changing value of the vertical capacitor 621. Movement parameter of the main body 10 is obtained by measuring the value of vertical capacitor 621, such as speed and acceleration of movement in a direction parallel to the first surface 100a of the first main body 100 in an acceleration sensor. Likewise, since the third electrode 211 is arranged on sidewall of the weight block 200, and the first electrode 110 is arranged in the first main body 100, when the main body 10 moves in a direction perpendicular to the first surface 100a of the first main body 100, the weight block 200 acted upon by inertia remains at rest. A distance between the third electrode 211 and the first electrode 110 will be changed, thereby changing value of the horizontal capacitor 611. Movement parameter of the main body 10 is obtained by measuring the value of the horizontal capacitor 611, such as speed and acceleration of movement in a direction perpendicular to the first surface 100a of the first main body 100 in an acceleration sensor.

The weight block 200 in the present invention adopts a double-layer structure including inner layer and outer layer. The inner layer is made of a material in low price, and the outer layer is made of a material used to fabricate electrodes. A weight of the weight block 200 may be increased by increasing volume of the weight block 200, and thus no cost will be increased. Therefore, the cost is reduced when the weight of the weight block is increased.

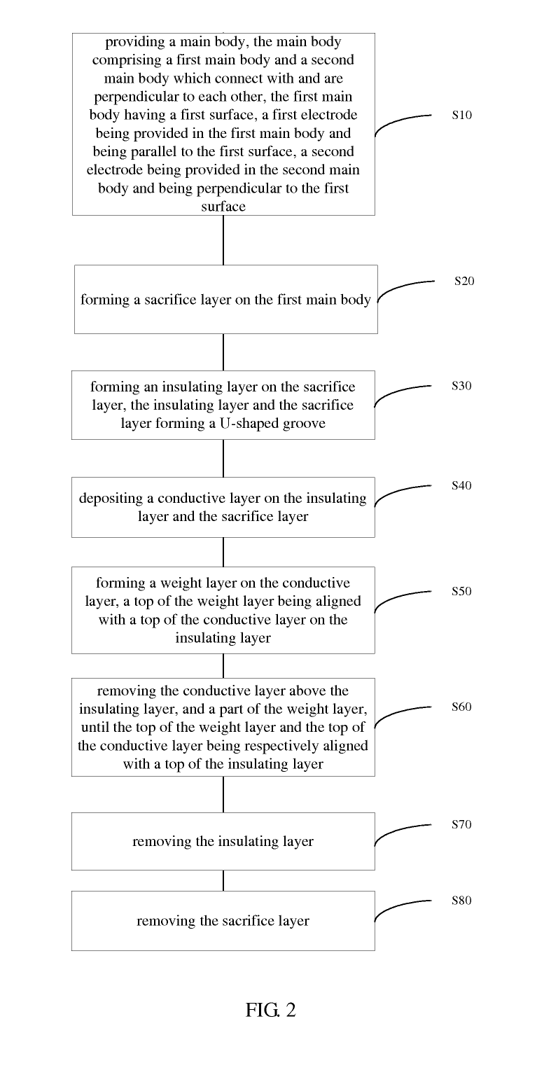

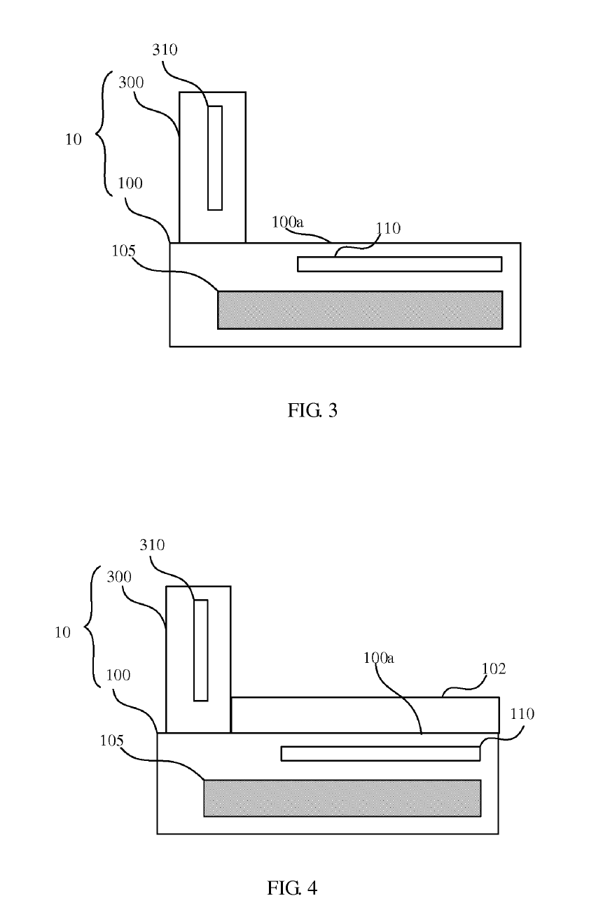

FIG. 2 schematically illustrates a flow chart of a method for manufacturing the inertia MEMS sensor of the present invention. FIGS. 3-10 are schematic cross-sectional views for illustrating the method for manufacturing the inertia MEMS sensor of the present invention step by step. Method for manufacturing the inertia MEMS sensor in FIG. 1 will be described below in conjunction with FIGS. 2-10.

Referring to FIG. 2, following steps are comprised.

S10, a main body is provided. The main body comprises a first main body and a second main body which connect with and are perpendicularly to each other. The first main body has a first surface. A first electrode is provided in the first main body and is parallel to the first surface. A second electrode is provided in the second main body and is perpendicular to the first surface.

S20, a sacrifice layer is formed on the first main body.

S30, an insulating layer is formed on the sacrifice layer. The insulating layer and the sacrifice layer form a U-shaped groove.

S40, a conductive layer is deposited on the insulating layer and the sacrifice layer.

S50, a weight layer is formed on the conductive layer. A top of the weight layer is aligned with a top of the conductive layer on the insulating layer.

S60, the conductive layer above the insulating layer, and a part of the weight layer are removed until the top of the weight layer and the top of the conductive layer are respectively aligned with a top of the insulating layer.

S70, the insulating layer is removed.

S80, the sacrifice layer is removed.

Detail description will be presented in conjunction with FIGS. 3-10.

Referring to FIG. 3, S10 is performed to provide a main body 10. The main body 10 comprises a first main body 100 and a second main body 300. The first main body 100 may be a semiconductor substrate. The semiconductor substrate is made of monocrystalline, polycrystalline, non-crystalline silicon or SiGe. It can also be made of Silicon on Insulator (SOI) or other material, such as InSb, PbTe, InAs, InP, GaAs or GaSb. The first main body 100 provides a first electrode 110 therein. The first electrode 110 is arranged parallel to a first surface 100a (top surface) of the main body 100. The first electrode 110 is made of Al, Ti, Cu, Co, Ni, Ta, Pt, Ag, Au or any combinations thereof. The first main body 100 may further comprise a semiconductor material layer 105 under the first electrode 110, such as a Si layer. The semiconductor material layer 105 has a MOS device therein.

The second main body 300 is provided on partial area of the first main body 100. The second main body 300 is made of insulating material, such as silicon oxide, silicon nitride, silicon carbide, silicon oxynitride, silicon dioxide containing nitrogen and carbon, or any combinations thereof. The second main body 300 provides a second electrode 310 perpendicular to the first surface 100a of the first main body 100 therein. The second electrode 310 is made of Al, Ti, Cu, W, Ta or any combinations thereof

Referring to FIG. 4, S20 is performed to form a sacrifice layer 102 on the first main body 100. The sacrifice layer 102 covers the first surface 100a of the first main body 100, such as forming the sacrifice layer 102 by CVD process. The sacrifice layer 102 is made of carbon, germanium or polyamide. Preferably, the sacrifice layer 102 is made of carbon with purity of at least 50%. Concretely, the sacrifice layer 102 is made of amorphous carbon, using PECVD (plasma-enhanced Chemical Vapour Deposited, PECVD) process, under conditions of temperature ranging from 350 centigrade to 450 centigrade, air pressure ranging from 1 torr to 20 torr, RF power ranging from 800 W to 1500 W, reaction gas of C3H6 and He, gas flow ranging from 1000 sccm to 3000 sccm, gas ratio of C3H6 to He ranging from 2:1 to 5:1.

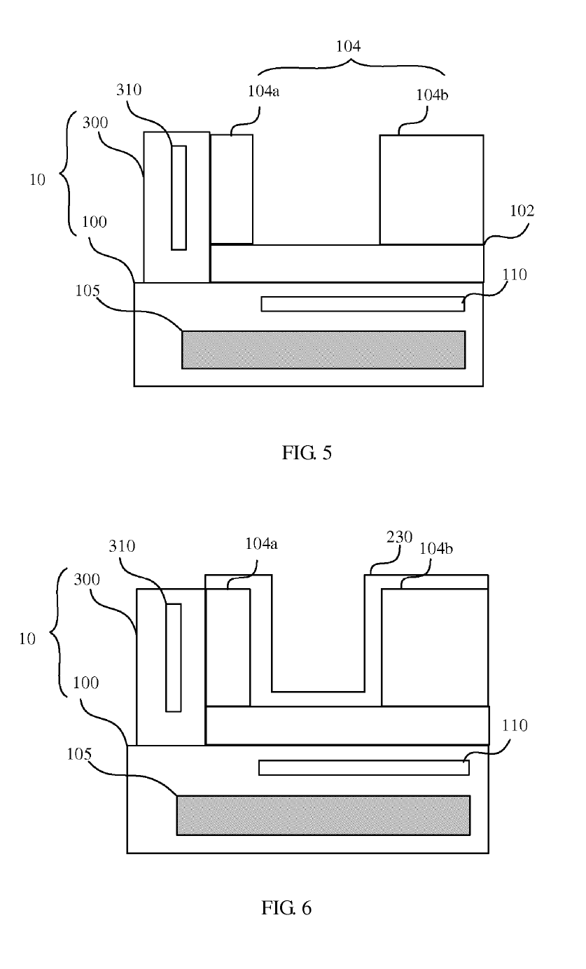

Referring to FIG. 5, S30 is performed to form an insulating layer 104 on the sacrifice layer 102. The insulating layer 104 at least comprises two parts which are not connected with each other. The two parts comprise a first part 104a and a second part 104b. For example, the insulating layer 104 is formed on the sacrifice layer 102 by CVD process. The insulating layer 104 is made of silicon oxide, silicon nitride, silicon carbide, silicon oxynitride, silicon dioxide containing nitrogen and carbon, or any combinations thereof. A thickness of the insulating layer 104 ranges from 1 μm to 15 μm.

Referring to FIG. 6, S40 is performed to deposit a conductive layer 230 on the insulating layer 104 and the sacrifice layer 102, by vapor deposition, especially to CVD or PVD. The conductive layer 230 is made of Al, Ti, Cu, Co, Ni, Ta, Pt, Ag, Au or any combinations thereof. A thickness of the conductive layer 230 ranges from 500 Å to 5000 Å.

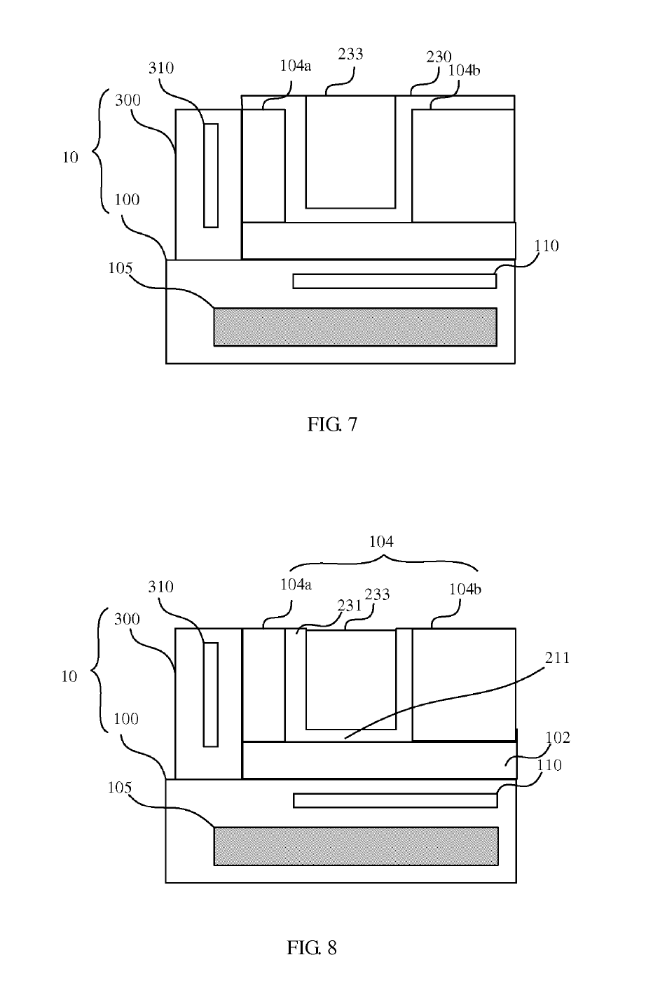

Referring to FIG. 7, S50 is performed to form a weight layer 233 on the conductive layer 230 above the sacrifice layer 102. Then the weight layer 233 is polished by CMP (chemical mechanical planarization, CMP) process until a top of the weight layer 233 is aligned with a top of the conductive layer 230 above the insulating layer 104.

Referring to FIG. 8, S60 is performed to remove a part of the weight layer 233, and the conductive layer 230 above the insulating layer 104. The rest of the conductive layer 230 comprises partial conductive layer 230 on sidewall of the insulating layer 104 (a forth electrode 231), and partial conductive layer 230 on the sacrifice layer 102 (a third electrode 211).

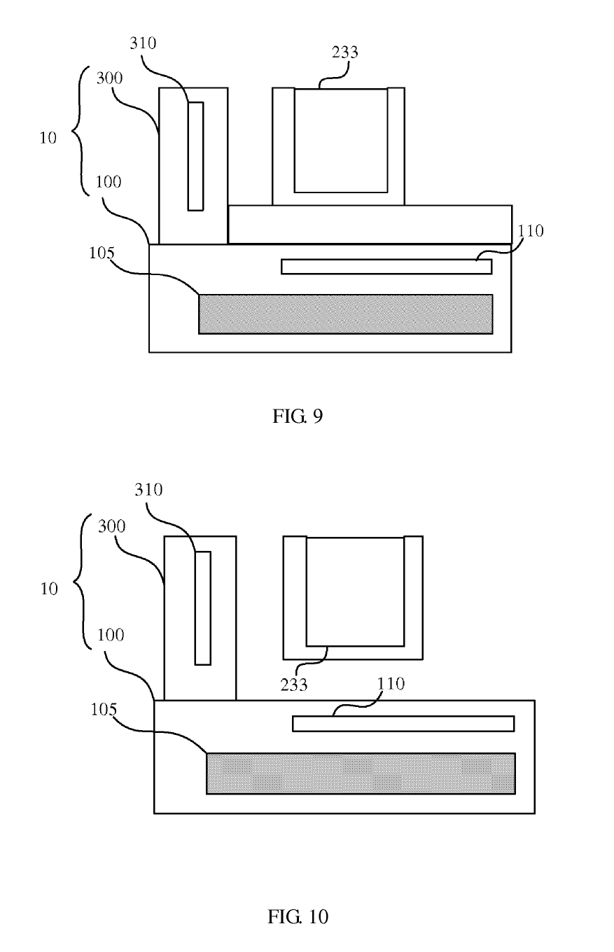

Referring to FIG. 9, S70 is performed to remove the insulating layer 104. The insulating layer 104 may be removed by etching or cleaning process.

Referring to FIG. 10, S80 is performed to remove the sacrifice layer 102. The sacrifice layer is removed by cleaning or ashing process, such as performing ashing process with oxygen plasma or nitrogen plasma. In this embodiment, the sacrifice layer 102 is made of compact amorphous carbon fabricated by PECVD process. Oxygen is used as removing gas and a heating temperature ranges from 350 centigrade to 450 centigrade. At the heating temperature, the compact amorphous carbon will not burn intensely, but will be oxidized to carbon dioxide gas. The carbon dioxide gas is expelled from the through holes and the sacrifice layer 102 is removed without effect on other apparatus.

After performing above steps, the weight block, which comprises the forth electrode 231, the third electrode 211 and the weight layer 233, are completed. The forth electrode 231, the second electrode 310, and a gaseous layer between the forth electrode 231 and the second electrode 310 constitute a vertical capacitor. The third electrode 211, the first electrode 110, and a gaseous layer between the first electrode 110 and the third electrode 211 constitute a horizontal capacitor. In the present invention, the main body 10 forms the second electrode 310 therein. When the main body 10 moves or rotates in a horizontal direction, the weight block 200 remains at rest. A value of the vertical capacitor constituted by the forth electrode 231 and the second electrode 310 is changed. Movement of the main body 10 is obtained by measuring the value of the vertical capacitor, such as speed, acceleration, rotation angles or rotation speed etc. Likewise, the main body 10 moves or rotates in a vertical direction, the weight block 200 remains at rest. A value of the horizontal capacitor constituted by the third electrode 211 and the first electrode 110 is changed. Movement of the main body 10 is obtained by measuring the value of the horizontal capacitor, such as speed, acceleration, rotation angles or rotation speed etc. Therefore, many sensors can be fabricated based on above embodiments.

The weight block 200 of the present invention adopts a double-layer structure. The inner layer is the weight layer, and the outer layer is an electrode. For providing a higher performance capacitor, the outer layer is made of SiGe, and the inner layer is made of silicon dioxide in a low price for increasing weight. Since the weight layer is in a low price, a bigger volume weight block can be fabricated. Even though increasing volume of the weight block, since the outer layer is thinner, less SiGe is used, thereby increasing the weight and reducing the cost.

Before performing S20, a mask layer may be provided on the second main body. The mask layer may be removed after performing S80.

In addition, after performing S60, a metal layer may be formed on the weight layer 233 and the forth electrode 231, such as Al or copper etc.

A weight block and a main body are movably connected according to different applications environment. For example, flexible parts may be horizontally arranged in an accelerated sensor to connect the weight block with the main body in a horizontal direction. Flexible parts may be vertically arranged in an accelerated sensor to connect the weight block with the main body in a vertical direction. With regard to gyroscope, a main body may provide an axis and a cantilever rotating around the axis therein. The weight block is connected to the main body through the cantilever, whereby the weight block rotates around the axis. For applications in different sensors, it can be obtained by one skilled in the art based on experience, and it is unnecessary to go into detail.

A sensor comprising one weigh block is presented in above embodiments. Besides, the present invention may be used for fabricating a sensor with many weigh blocks according to above embodiments. For example, many second main bodies and third electrodes may be arranged on the main body.

Apparently, those skilled in the art should recognize that various variations and modifications can be made without departing from the spirit and scope of the present invention. Therefore, if these variations and modifications fall into the scope defined by the claims of the present invention and its equivalents, then the present invention intends to cover these variations and modifications.

What is claimed is:

1. An inertia MEMS sensor comprising:
a main body comprising a first main body with a first surface, and a second main body connecting with and being perpendicular to the first surface, a first electrode being provided in the first main body and being parallel to the first surface, a second electrode being provided in the second main body and being perpendicular to the first surface; and
a weight block being suspended in a space defined by the first main body and the second for being movable relative to the main body, and comprising a third electrode, a forth electrode and a weight layer, the third electrode being parallel to the first surface, the forth electrode being perpendicular to the first surface, the third electrode connecting with the forth electrode to form a U-shaped groove for accommodating the weight layer therein.

2. The inertia MEMS sensor according to claim 1, wherein the first main body further comprises a semiconductor material layer under the first electrode, a MOS device being provided in the semiconductor material layer.

3. The inertia MEMS sensor according to claim 1, wherein the first electrode is made of Al, Ti, Cu, Co, Ni, Ta, Pt, Ag, Au or any combinations thereof.

4. The inertia MEMS sensor according to claim 1, wherein the second main body is made of silicon oxide, silicon nitride, silicon carbide, silicon oxynitride, silicon dioxide containing nitrogen and carbon, or any combinations thereof.

5. The inertia MEMS sensor according to claim 1, wherein the second electrode is made of Al, Ti, Cu, W, Ta or any combinations thereof.

6. The inertia MEMS sensor according to claim 1, wherein the third electrode and the forth electrode are respectively made of Al, Ti, Cu, Co, Ni, Ta, Pt, Ag, Au or any combinations thereof.

7. The inertia MEMS sensor according to claim 1, wherein the weight layer is made of W, SiGe, Ge, Al, silicon oxide, silicon nitride or any combinations thereof.

8. A method for manufacturing an inertia MEMS sensor in claim 1, comprising:
providing a main body, the main body comprising a first main body and a second main body which connect with and are perpendicular to each other, the first main body having a first surface, a first electrode being provided in the first main body and being parallel to the first surface, a second electrode being provided in the second main body and being perpendicular to the first surface;
forming a sacrifice layer on the first main body;
forming an insulating layer on the sacrifice layer, the insulating layer and the sacrifice layer forming a U-shaped groove;
depositing a conductive layer on the insulating layer and the sacrifice layer;
forming a weight layer on the conductive layer, a top of the weight layer being aligned with a top of the conductive layer on the insulating layer;
removing the conductive layer above the insulating layer, and a part of the weight layer, until the top of the weight layer and the top of the conductive layer being respectively aligned with a top of the insulating layer;
removing the insulating layer; and
removing the sacrifice layer.

9. The method according to claim 8, wherein the sacrifice layer is made of carbon with purity of at least 50%.

10. The method according to claim 8, wherein the sacrifice layer is formed by PECVD at temperature ranging from 350 centigrade to 450 centigrade.

11. The method according to claim 8, wherein removing the sacrifice layer comprises ashing with oxygen plasma or nitrogen plasma.

12. The method according to claim 8, wherein depositing a conductive layer for covering the insulating layer and the sacrifice layer is performed by CVD and/or PVD.
